(19) United States
(12) Patent Application Publication
(10) Pub. No.: US 2006/0001556 A1
(43) Pub. Date: Jan. 5, 2006

(54) Method and apparatus for critical data entry

(76) Inventor: Howard Shelton Lambert, Southhampton (GB)

Correspondence Address: IBM CORPORATION, 3039 CORNWALLIS RD., DEPT. T81 / B503, PO BOX 12195, REASEARCH TRIANGLE PARK, NC, 27709, US

(21) Appl. No.: 11/170,815

(22) Filed: Jun. 30, 2005

(30) Foreign Application Priority Data
Jul. 1, 2004 (GB) 0414712.0

(51) Int. Cl. H03M 7/34

(52) U.S. Cl. 341/51

(57) ABSTRACT

There is provided a method for data entry comprising: receiving an original data string entered by a user; requesting that a user input a verification data string; receiving verification data string characters as they are input by the user in response to the request for input; and providing audio or visual verification feedback of a comparison of the original data string with each verification data string character as it is received. The solution provides feedback on a verification data string (also know as a confirmation input) for corresponding original input data just entered by a user. Optionally, the data strings are masked so that the original data string and the verification data string are not visible to the user.

This invention pertains to computers, computer software, and other information technology systems and methods and, more particularly, to such systems and methods for critical data entry.

### BACKGROUND of the INVENTION

Some computer programs require that a user enter critical data during the execution of the program; such critical data is required to be 100% correct, otherwise the program can fail. For instance, 100% accuracy is crucial for entering or verifying a password, a certificate, an encryption key, or an email address.

In order to check that such critical data is correct, one type of critical data entry method asks the user to enter verification data to verify the original data. The program will then check the original data with this verification data and inform the user if there is an inconsistency. The verification data and, in some cases, the original data need to be checked and compared by the user to locate the inconsistency.

However, some users find it difficult to locate where the inconsistency has occurred and the difficulties increase as the length of the data increases. This problem is amplified in security cases where the data characters are masked on the graphical user interface to obscure them, for instance, where the critical data is an encryption key. In this case it is impossible for the user to determine where the inconsistency in the original data and verification data is. In particular, this is a nuisance when the critical data is a long string and needs to be completely re-entered two times.

Standard dialog boxes in a computing environment do not provide any feedback for password prompts, showing that the minimum number of characters has been reached. Also, when re-entering the data for verification, there is no feedback as to whether the original and verification data match.

### SUMMARY OF INVENTION

According to a first aspect of the present invention, there is provided a method for data entry comprising: receiving an original data string entered by a user; requesting that a user input a verification data string; receiving verification data string characters as they are input by the user in response to the request for user input; and providing verification feedback of a comparison of the original data string with each verification data string character as it is received.

In another embodiment, receiving of the original data string comprises receiving original data string characters as they are input by the user and providing rule feedback of each original data string character as it is received according to a rule determining the form of the original data string.

In another embodiment, the rule determining the form of the original data string defines the minimum length of the original data string and the rule feedback indicates when the minimum length of the original data string has been exceeded.

In another embodiment, the verification feedback comprises a positive indication that the verification data string character matches the character in the corresponding position of the original data string.

In yet another embodiment, the data strings may be masked so that the original data string and the verification data string are not visible to the user.

The feedback may be audio feedback and, in the case of a favorable comparison, one type of sound may be generated after the character is received and compared; for example, a short discernable low volume noise. In the case of an unfavorable comparison, a different type of sound is generated; for example, a longer, higher volume sound.

The feedback may be visual, with one type or style of the character or verification data string in the case of a favorable comparison; for example, a green color or a bold character. In the case of an unfavorable comparison, a different style of character is used; for example, a red character or red string of characters.

### BRIEF DESCRIPTION of the DRAWINGS

In order to promote a fuller understanding of this and other aspects of the present invention, an embodiment of the invention will now be described, by means of example only, with reference to the accompanying drawings in which:

FIG. 1 is a schematic representation of a computer platform in a user environment, including a critical data entry object of the preferred embodiment;

FIG. 2 is a schematic representation of a string entry method of the preferred embodiment;

FIG. 3 is a schematic representation of an original data feedback method of the preferred embodiment; and

FIG. 4A to 4F are example dialog windows of the preferred embodiment in operation.

### DESCRIPTION OF THE EMBODIMENTS

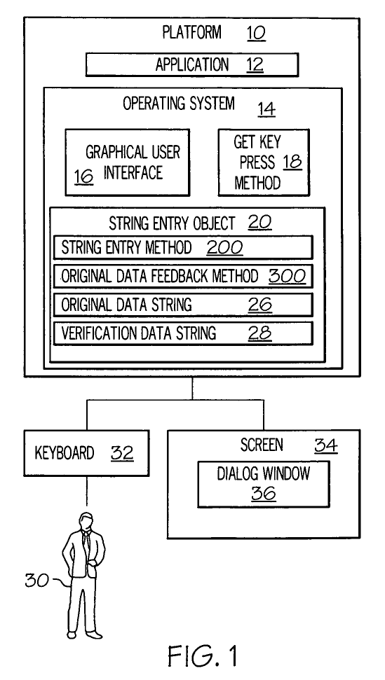

FIG. 1 is a schematic representation of a computer platform 10 and user 30. The platform is computing hardware which executes an application 12 using an operating system 14. The platform 10 is connected to a keyboard 32 and computer screen 34. Only these components are needed to describe the preferred embodiment so other features of the platform will not be described.

In the preferred embodiment the application 12 requires critical data to operate and uses objects and methods in the operating system 14 to achieve this. The important aspect of the application 12 is that it requires input of critical data and requests that the operating system 14 to provide such critical data, no other aspects of the application need be described.

In the preferred embodiment the operating system comprises the components but there is no reason why the components could not be included in the application 12; in the platform 10; or even in a separate computing entity. The preferred embodiment is described in the context of an operating system without expanding on known aspects of operating systems. The preferred embodiment is application independent; operating system independent and platform independent.

The operating system 12 includes: a graphical user interface 16; a get key press method 18; and a string entry object 20.

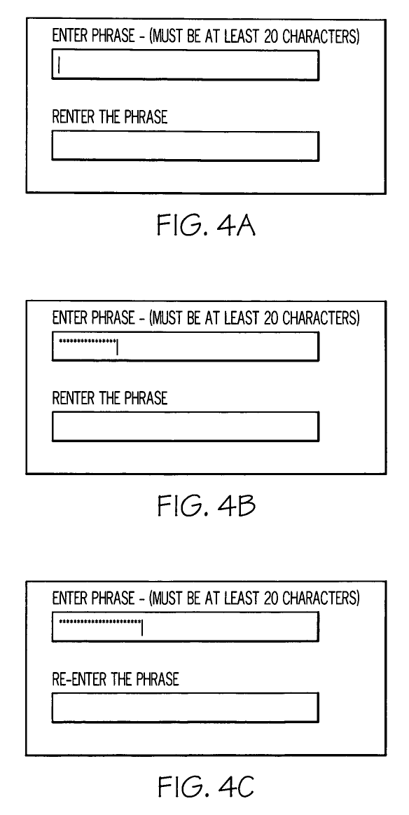

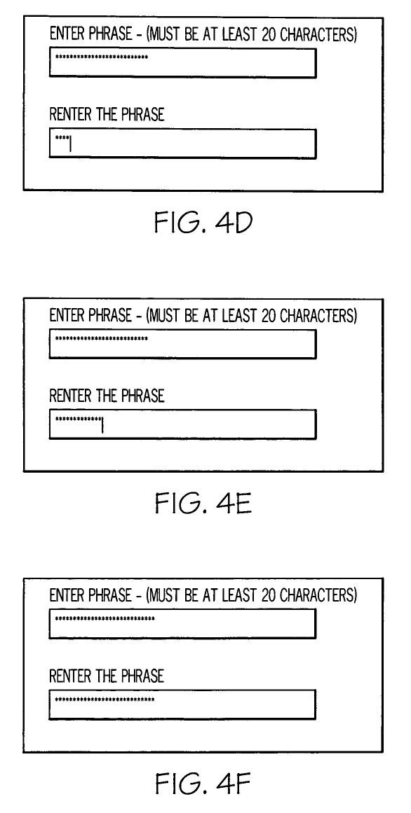

The graphical user interface 16 accepts user input from the keyboard 32 or other input peripheral and creates visual output on the computer screen 34 in the form of a dialog window 36. See FIG. 1 for an abstract dialog window 36 in the context of the platform 10 and FIGS. 4A to 4F for more detailed dialog windows in isolation of the platform.

The get key press method 18 is a routine in the operating system 14 which notifies a requesting method (in this case the string entry method 200 and the original data feedback method 300) when a key is pressed and what the key character is.

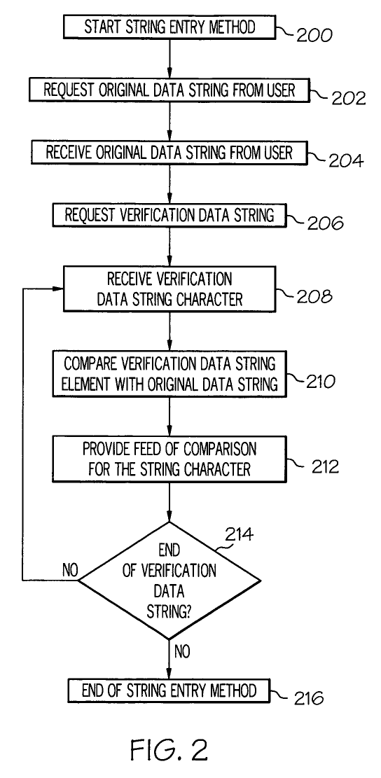

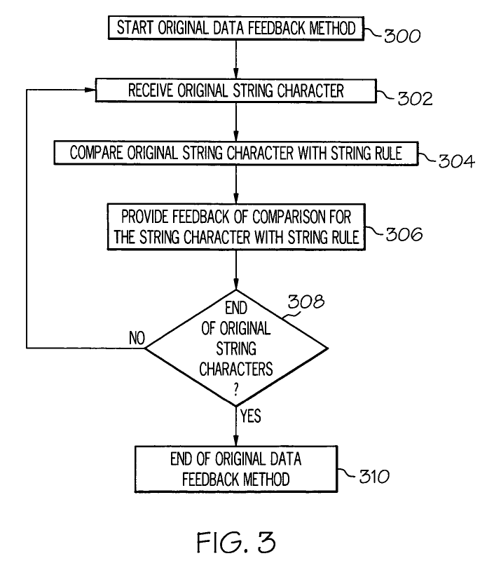

The string entry object 20 comprises: string entry method 200 (described below with respect to FIG. 2); original data feedback method 300 (described below with respect to FIG. 3); original data string 26; and verification data string 28. The string variables 26 and 28 store the original data string and verification data string respectively for working and final output purposes of the string entry method 200 and original data feedback method 300.

FIG. 2 is a schematic representation of a string entry method of the preferred embodiment. Step 200 is the start of the string entry method. It is this step 200 that is called by the application. In Step 202 the graphical user interface displays a request for the original data string by presenting a dialog window 36 and prompt to the user. Step 204 receives the original data string from user either with a standard input keyboard routine or using the start original data feedback method 300 routine. Step 206 requests the verification data string from the user. Step 208 receives verification data string character by calling the get key press method 18. In step 210 the verification data string character is compared with a corresponding original data string character. Corresponding in this case refers to the characters in the same position in the original string and the verification string. In step 212 feedback is provided regarding the comparison for the original data string character. Step 214 checks for the end of verification data string usually occurring when a return character is received from the get key press routine. If it is not the end and another character is received then control is passed back to step 208. If the end of the verification data string is reached then control is passed to the end step 216. Step 216 ends the string entry method and returns control to the application.

FIG. 3 is a schematic representation of an original data feedback method of the preferred embodiment. Step 300 is the start of the original data feedback method and where the original data string variable 26 is reset. Step 302 receives an original string character after calling the get key press method 18. Step 304 compares the original data string character with a string rule, For example, one rule is that the string has a minimum length. Step 306 provides feedback of the comparison for the string data character with string rule. Step 308 checks if the end of original data string has been reached usually by detecting a return character from the get key press method 18 but other keys and buttons can be used. If no return character is detected then control is passed back to step 302. If a return character is detected then control is passed to step 310. Step 310 is the end of original data string feedback method and control is passed back to the application or back to the start string entry method 200.

FIG. 4A to 4F are example dialog windows 36 of the preferred embodiment in operation.

FIG. 4A shows an example of an empty dialog window created at the start of string entry method 200 that provides visual (and audio) feedback as the characters are entered.

FIG. 4B shows a dialog window in which the minimum number of characters for the original data string has not yet entered and the original data string is highlighted in red because the string rule (original data feedback method 300) has not been complied with yet.

FIG. 4C shows a dialog window in which the string rule has been complied with and more than the minimum characters have been entered. The original data string is changed to green and a “beep” was sounded when the minimum length is reached.

FIG. 4D shows a dialog window in which verification data string characters do not match the original data string. In this case the string entry method 200 turns the verification data string red and an error “Beep” is sounded.

FIG. 4E shows a dialog window in which the verification data string characters have been entered correctly so that the string entry method 200 gives the string green attributes.

FIG. 4F shows a dialog window in which the verification data string has been entered correctly. The string entry method 200 switches the background color of the input areas to green and a success “Beep” is sounded.

What is claimed:

1. A method for data entry comprising:
receiving an original data string entered by a user;
requesting that a user input a verification data string;
receiving verification data string characters as they are input by the user in response to the request for input; and
providing verification feedback of a comparison of the original data string with each verification data string character as it is received.

2. A method as in claim 1, wherein receiving of the original data string comprises receiving original data string characters as they are input by the user and providing rule feedback of each original data string character as it is received, according to a rule determining the form of the original data string.

3. A method as in claim 2, wherein the rule determining the form of the original data string defines the minimum length of the original data string, and the rule feedback indicates when the minimum length of the original data string has been exceeded.

4. A method as in claim 1, wherein the verification feedback comprises a positive indication that the verification data string character matches the character in the corresponding position of the original data string.

5. A method as in claim 1, wherein the data strings are masked so that the original data string and the verification data string are not visible to the user.

6. A system for data entry comprising:
means for receiving an original data string entered by a user;
means for requesting that a user input a verification data string;
means for receiving verification data string characters as they are input by the user in response to the request for input; and
means for providing verification feedback of a comparison of the original data string with each verification data string character as it is received.

7. A system as in claim 6, wherein receiving of the original data string comprises receiving original data string characters as they are input by the user and providing feedback of each original data string character as it is received, according to a rule determining the form of the original data string.

8. A system as in claim 7, wherein the rule determining the form of the original data string defines the minimum length of the original data string and the original data feedback indicates when the minimum length of the original data string has been exceeded.

9. A system as in claim 6, wherein the feedback comprises a positive indication that the verification data string character matches the corresponding character in the original data string.

10. A system as in claim 6, wherein the data strings are masked so that the original data string and the verification data string are not visible to the user.

11. A computer program product for data entry, said computer program product comprising computer program instructions stored on a computer-readable storage medium for, when loaded into a computer and executed, causing a computer to carry out the steps:
receiving an original data string entered by a user;
requesting that a user input a verification data string;
receiving verification data string characters as they are input by the user in response to the request for input; and
providing verification feedback of a comparison of the original data string with each verification data string character as it is received.

12. A computer program product as in claim 11, wherein receiving of the original data string comprises receiving original data string characters as they are input by the user and providing feedback of each original data string character as it is received, according to a rule determining the form of the original data string.

13. A computer program product as in claim 12, wherein the rule determining the form of the original data string defines the minimum length of the original data string and the original data feedback indicates when the minimum length of the original data string has been exceeded.

14. A computer program product as in claim 11, wherein the feedback comprises a positive indication that the verification data string character matches the corresponding character in the original data string.

15. A computer program product as in claim 11, wherein the data strings are masked so that the original data string and the verification data string are not visible to the user.
